(19) United States
(12) Patent Application Publication
(10) Pub. No.: US 2011/0069470 A1
(43) Pub. Date: Mar. 24, 2011

(54) Electromagnetic interference noise reduction board using electromagnetic bandgap structure

(75) Inventors: Kang-Wook Bong, Seoul (KR); Han Kim, Yongin-si (KR); Mi-Ja Han, Junjoo-si (KR)

(73) Assignee: SAMSUNG ELECTRO-MECHANICS CO., LTD., Suwon (KR)

(21) Appl. No.: 12/654,371

(22) Filed: Dec. 17, 2009

(30) Foreign Application Priority Data
Sep. 22, 2009 (KR) 10-2009-0089666

(51) Int. Cl. H05K 9/00

(52) U.S. Cl. 361/818

(57) ABSTRACT

An EMI noise reduction board is disclosed. The electromagnetic interference (EMI) noise reduction board having an electromagnetic bandgap structure for shielding a noise includes a first area having a ground layer and a power layer, a second area placed in a side portion of the first area having an electromagnetic bandgap structure therein. The electromagnetic bandgap structure includes a plurality of first conductive plates placed along the side portion of the first area, a plurality of second conductive plates placed on a planar surface that is different from the first conductive plates so as to overlap with the first conductive plates, and a via configured to connect the first conductive plate and the second conductive plate.

### CROSS-REFERENCE TO RELATED APPLICATIONS

This application claims the benefit of Korean Patent Application No. 10-2009-0089666, filed with the Korean Intellectual Property Office on Sep. 22, 2009, the disclosure of which is incorporated herein by reference in its entirety.

### BACKGROUND

1. Technical Field

The present invention relates to a board, more specifically to a noise reduction board that can reduce an EMI noise by use of an electromagnetic bandgap structure.

2. Description of the Related Art

As the operating frequencies of electric products become higher, electromagnetic interference (EMI) has been perceived as a chronic noise problem. Particularly, the operating frequencies of electronic products have reached a few ten megahertzs (MHz), or even a few gigahertzs (GHz), making the EMI problems more serious. Subsequently, finding a solution to the problems is desperately needed. Among the EMI problems occurring at a board, a solution for the noise problems particularly occurred at the edge of the board has not been little studied, making it difficult to completely shield the noise at the board.

EMI noise refers to a noise that creates a noise problem caused by interference when an electromagnetic (EM) wave generated in one electrical circuit, component or part is transferred to another electrical circuit, component or part. The EMI noise can be broadly categorized into two types, namely, a radiation noise (reference numerals 10 and 30 in FIG. 1) and a conduction noise (reference numeral 20 in FIG. 1).

The radiation noise 10, which is radiated towards an upper side of the board (that is, the mounting surface of an electronic part), may be commonly shielded by covering an upper portion of the board by use of an electromagnetic shielding cap, for example, a metal cap. However, few studies have tried to find an effective solution for the radiation noise 30 (hereinafter, referred to as an “edge noise”), which is radiated towards the outside of the board when a conduction noise 20 inside the board is conducted to the edge of the board.

If a technology is developed to reduce the edge noise at the edge of the board through a simple modification of the board structure, it is expected to significantly reduce the development time and costs, compared to the conventional method, which has tried to solve the problem through the use of a metal cap or a circuit. Additionally, such technology can have more merits in terms of space utilization and power consumption, and can easily remove a noise in a frequency band of a few gigahertzs (GHz), making it effective in solving the EMI noise problem at the edge of the board.

### SUMMARY

The present invention provides an electromagnetic interference (EMI) noise reduction board that can shield the radiation noise radiated from the edge of the board, by inserting an electromagnetic bandgap structure capable of shielding a noise ranging a certain frequency band into a portion of the board corresponding to the edge of the board.

The present invention also provides an EMI noise reduction board that can be advantages in space utilization, production cost and power consumption, by simply modifying the structure of the board so as to easily shield the radiation noise radiated from the edge of the board.

Other problems that the present invention solves will become more apparent through the following embodiments described below.

An aspect of the present invention features an electromagnetic interference (EMI) noise reduction board having an electromagnetic bandgap structure for shielding a noise, including: a first area having a ground layer and a power layer; a second area placed in a side portion of the first area having an electromagnetic bandgap structure therein. The electromagnetic bandgap structure can include a plurality of first conductive plates placed along the side portion of the first area, a plurality of second conductive plates placed on a planar surface that is different from the first conductive plates so as to overlap with the first conductive plates, and a via configured to connect the first conductive plate and the second conductive plate.

The first area and the second area can be a multi-layer having 4 or more layers, and the via can be a penetration via that penetrates the second area vertically. Also, the via can be a blind via.

In addition, one of the first conductive plate and the second conductive plate can have a bump or an indentaion shape corresponding to an outline shape of the first area, and at least any one pair of adjacent conductive plates among the plurality of first conductive plates can be electrically connected to each other by a connection line.

The first conductive plate can be electrically connected to the ground layer by a connection line, and the second area can be selectively arranged in a certain portion of the side portion of the first area.

### BRIEF DESCRIPTION OF THE DRAWINGS

FIG. 1 is a drawing for describing an electromagnetic interference (EMI) noise problem;

FIG. 2 is a sectional view of an EMI noise reduction board according to an embodiment of the present invention;

FIG. 3 is a side view of an EMI noise reduction board according to an embodiment of the present invention;

FIG. 4 is a front view of an EMI noise reduction board according to an embodiment of the present invention;

FIG. 5 is a perspective view of an EMI noise reduction board according to an embodiment of the present invention;

FIGS. 6 to 15 are front views of EMI noise reduction boards according to various embodiments of the present invention; and

FIGS. 16 to 18 are plan views of EMI noise reduction boards according to various embodiments of the present invention.

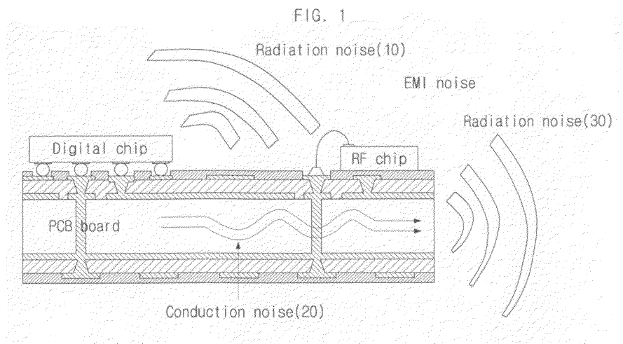

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention.

In the description of the present invention, certain detailed descriptions of related art are omitted when it is deemed that they may unnecessarily obscure the essence of the invention.

While such terms as “first” and “second,” etc., may be used to describe various components, such components must not be limited to the above terms. The above terms are used only to distinguish one component from another. For example, a first component may be referred to as a second component without departing from the scope of rights of the present invention, and likewise a second component may be referred to as a first component.

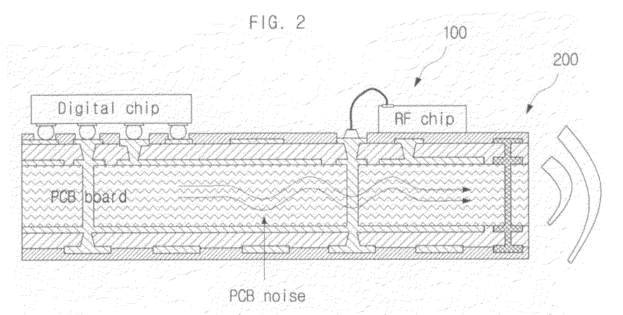

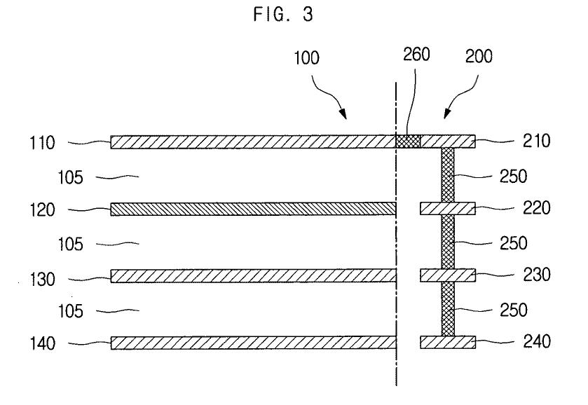

The object of an EMI noise reduction board according to an embodiment of the present invention is not to shield a conductive noise inside the board but to prevent the conductive noise that is conducted to the edge of the board from being radiated to the outside of the board. For this, as shown in FIGS. 2 and 3, a printed circuit board according to an embodiment of the present invention includes: the first area 100 having a ground layer 110 and a power layer 120; and the second area 200 placed in a side portion of the first area 100 having an electromagnetic bandgap structure (hereinafter “EBG structure”) therein. The EBG structure includes a plurality of first conductive plates 210 placed along the side portion of the first area 100, a plurality of second conductive plates 220 placed on a planar surface that is different from the first conductive plate 210 so as to overlap with the first conductive plate 210; and vias 250, 250a configured to connect the first conductive plate 210 and the second conductive plate.

As mentioned above, the conductive plates 210, 220 and a dielectric 105, which is interposed between the conductive plates 210, 220, constitue a capacitance component, and the vias 250, 250a constitute an inductance component. The EBG structure for shielding a noise, namely, an L-C filter is constituted by combination of the capacitance component and the inductance component.

As shown in FIG. 3, the printed circuit board according to an embodiment of the present invention has a structure of shielding an EMI noise radiated from the side portion of the board by forming the conductive plates 210, 220, 230, 240 on the edge portion of the board, overlapping the plates, and connecting the plates by the vias 250, 250a. Since a capacitance value between an upper layer and a lower layer can be increased due to the conductive plates 210, 220, 230, 240 that are overlapped to one another, the effect of shielding the EMI noise, which is conducted to the edge of the board, from being radiated to the outside of the board can be increased.

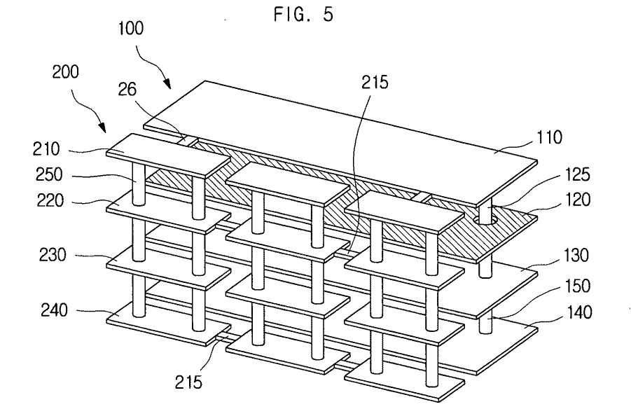

A plurality of metal layers 110, 120, 130, 140, such as the ground layer 110 and the power layer 120, are provided on the first area 100. FIGS. 3 and 5 show a structure in which the ground layer 110 is provided on a top layer and the power layer 120 is provided below the ground layer 110. Two metal layers 130, 140 provided below the power layer 120 may have a structure of being connected to the ground layer 110 by the via 150, as shown in FIG. 5. A clearance hole can be formed on the power layer 120, for electrical separation from the via 150.

However, the configuration of the first area 100 as described above is just an example, and thus changes on the configuration and arrangement of the first area 100 can be made in various ways.

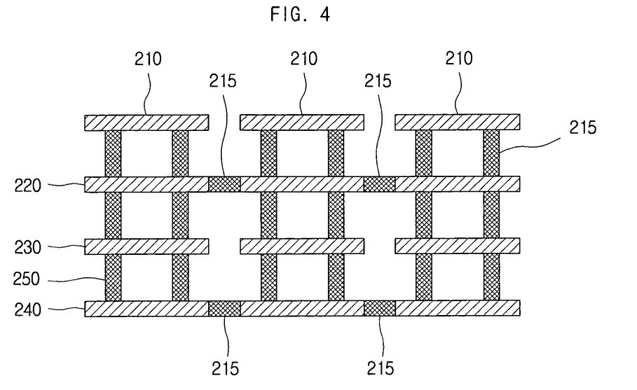

The plurality of conductive plates 210, 220, 230, 240 are arranged to be overlapped to one another in the second area 200 placed on the side portion of the first area 100, in which the ground layer 110 and the power layer 120 are provided, as shown in FIGS. 4 and 5. In detail, the plurality of first conductive plates 210 are arranged on a same planar surface along the side portion of the first area 100, and the second conductive plates 220 are arranged on a planar surface that is different from the first conductive plates 210 along the side portion of the first area 100. Here, the second conductive plates 220 are arranged to be overlapped with the corresponding first conductive plates 210. These overlapped first conductive plates 210 and second conductive plates 220 are connected to one another by the vias 250.

Here, the first conductive plate and the second conductive plate are not used to indicate a conductive plate configured to perform a specific function, but to distinguish conductive plates 210, 220, 230, 240 that are arranged on different planar surfaces. Moreover, each of the conductive plates 210, 220, 230, 240 can have the same size and shape, but it is also possible to have a different size or shape, as required by design, if necessary.

Moreover, an insulator (105 in FIG. 3) or a dielectric for an interlayer isolation is interposed between the conductive plates 210, 220, 230, 240.

Meanwhile, as shown in FIGS. 3 to 5, the first area 100 and the second area 200 can be a multi-layer with 4 or more layers, and the via 250 can be a penetration via that penetrates the second area 200 vertically. When the second area 200 is a multi-layered structure, the conductive plates 210, 220, 230, 240 on each layer are entirely overlapped with the conductive plates on different layers so that it is relatively easy to implement the interlayer connection by using the penetration via 250. As a result, the manufacturing process can be simplified so that the total manufacturing cost can be reduced.

Meanwhile, as shown in FIGS. 3 and 5, the first conductive plate 210 can be electrically connected to the first area 100, i.e., the ground layer 110, by a connection line 260. When the first conductive plate 210 is connected to the ground layer 110 in this way, it is possible to secure a relatively large ground so that the noise reduction effect can be further improved.

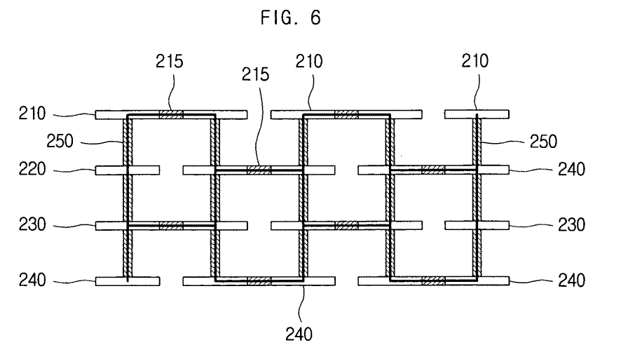

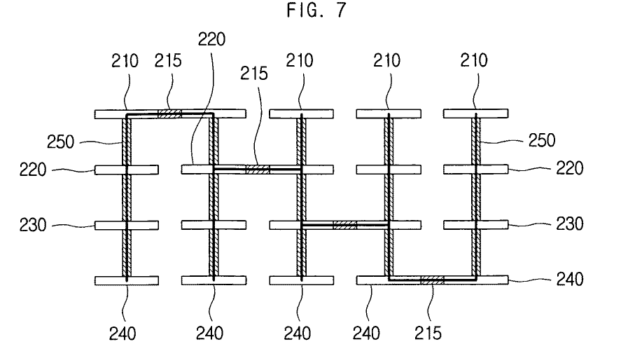

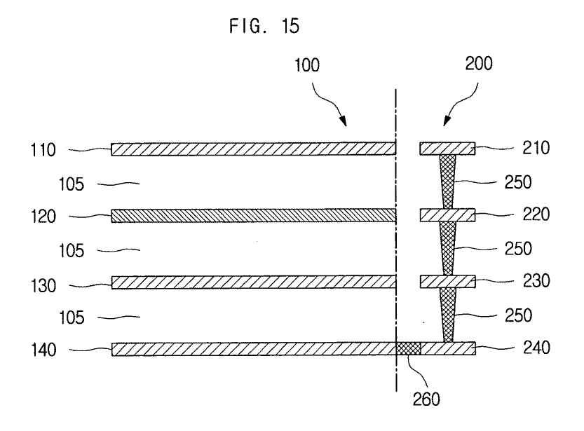

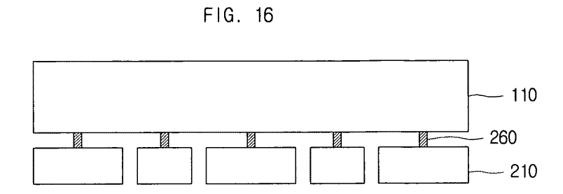

FIGS. 6 to 15 show various alternatives of the EBG structure that is inserted into the second area 200.

Referring to FIG. 6 first, at least any one pair of adjacent conductive plates among the plurality of first conductive plates 210 can be electrically connected to each other by a connection line 215. When the connection line 215 is formed between the adjacent first conductive plates 210, it becomes possible to add the inductance component between the first conductive plates 210 so that a greater freedom in design can be provided for shielding the noise more effectively. Other conductive plates 220, 230, 240 as well as the first conductive plate 210 can be connected between any pair of adjacent conductive plates by the connection line 215 to add the inductance component.

In the EBG structure shown in FIGS. 6 to 8, all conductive plates in the second area 200 are electrically connected to one another within the second area 200 by the penetration via 250 and the connection line 215.

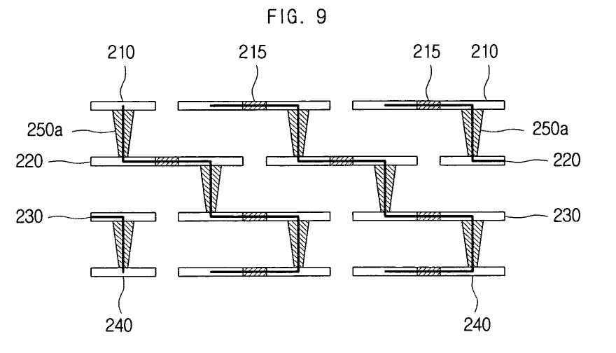

Meanwhile, in the EBG structure shown in FIG. 9, some conductive plates form an independent path, and each of these conductive plates is connected to the ground layer 110 in first area 100 by at least one connection line 260.

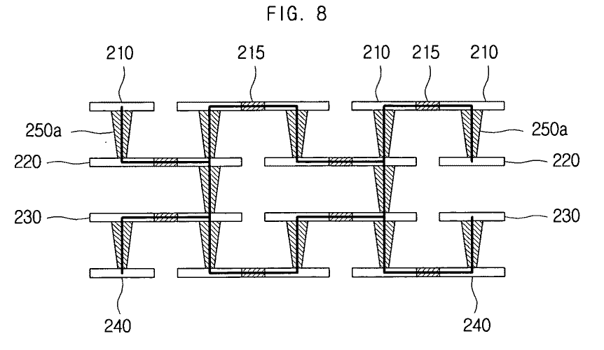

Although the aforementioned embodiments show a structure of using penetration via 250, which penetrates the second area 200, to electrically connect each of the conductive plates 210, 220, 230, 240 in the second area 200, it is also possible for the conductive plates 220, 240 to be respectively connected by a blind via 250a, as shown in FIGS. 8 and 9.

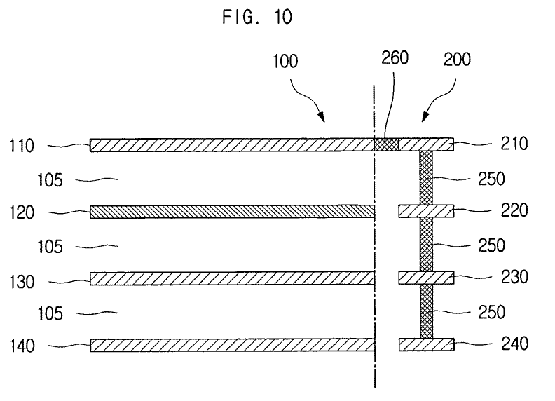

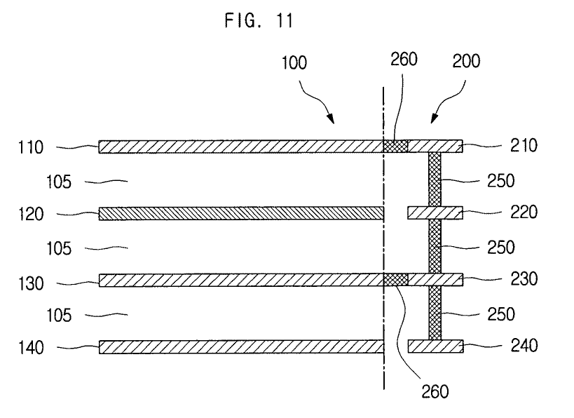

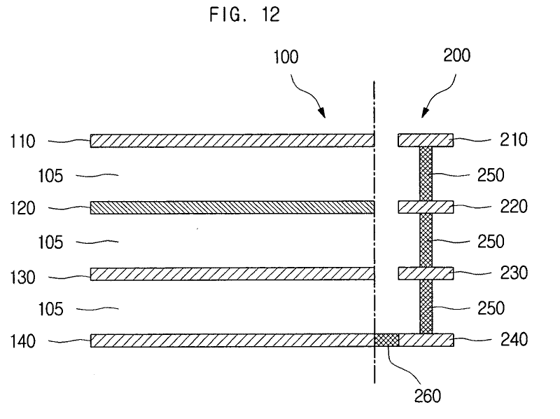

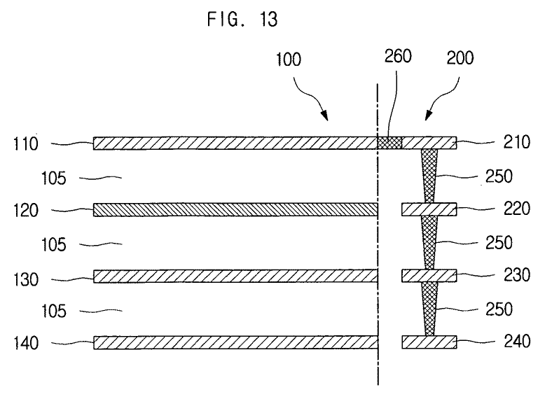

FIG. 10 shows a structure in which the first conductive plate 210 in the second area 200 is solely connected to the top layer of the first area 100, namely the ground layer 110, by the connection line 260. However, the embodiment of the present invention is not intended to this structure, and as shown in FIG. 11, other conductive plates in the second area can be also connected to other layers in the first area by the connection line. Moreover, as shown in FIG. 12, the first area can be directly connected to the bottom layer of the second area by the connection line.

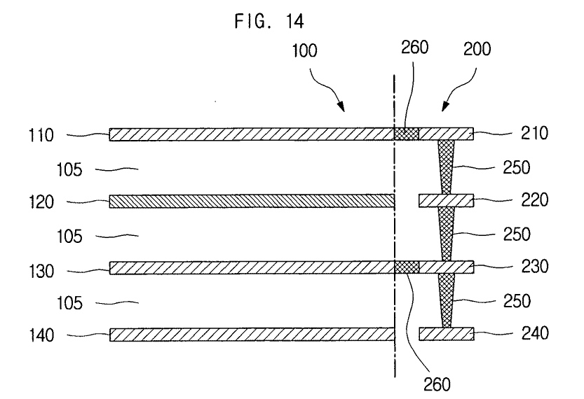

FIGS. 13 to 15 shows structures corresopndind to those in FIGS. 10 to 12, respectively, and in detail, the penetration via 250 in FIGS. 10 to 12 is replaced by the blind via 250a.

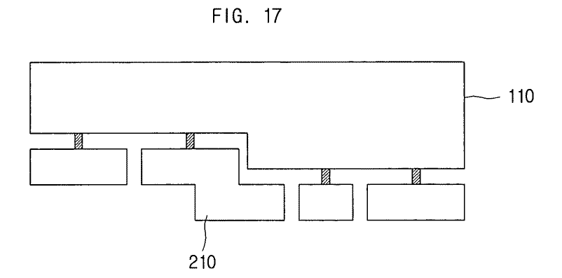

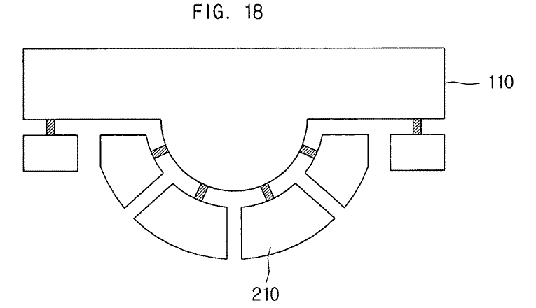

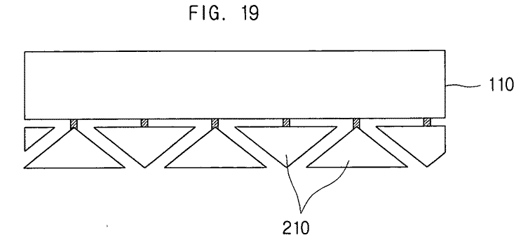

In addition, as shown in FIG. 16, when the side portion of the first area 100 has a rectangular shape, the first conductive plate 210 in the second area 200 also has a rectangular shape, but when the first area 100 has a shape other than a retangle, as shown in FIGS. 17 to 19, the first conductive plate 210 in the second area 200 also has an outline that can be a bump or an indentaion in various shapes corresponding to the first area 100. Namely, the first conductive plate 210 can have a bent shape, as shown in FIG. 17, a curved shape, as shown in FIG. 18, or a triangular shape arranged in a row, as shown FIG. 19.

Meanwhile, the second area 200 into which the EBG structure is inserted can be arranged on the whole side portion of the first area 100, but it is also possible to be selectively arranged on a certain portion. By arranging the second area 200 on a certain portion, it is possible to selectively shield the noise from the desired portion, thereby reducing the manufacturing cost.

While the spirit of the present invention has been described in detail with reference to particular embodiments, the embodiments are for illustrative purposes only and shall not limit the present invention. It is to be appreciated that those skilled in the art can change or modify the embodiments without departing from the scope and spirit of the present invention.

What is claimed is:

1. An electromagnetic interference (EMI) noise reduction board having an electromagnetic bandgap structure for shielding a noise, comprising:
a first area having a ground layer and a power layer; and
a second area placed in a side portion of the first area and having an electromagnetic bandgap structure therein so as to shield an EMI noise radiated to the outside through the side portion of the first area,
wherein the electromagnetic bandgap structure comprises:
a plurality of first conductive plates placed along the side portion of the first area;
a plurality of second conductive plates placed on a planar surface that is different from the first conductive plates so as to overlap with the first conductive plates; and
a via configured to connect the first conductive plate and the second conductive plate.

2. The EMI noise reduction board of claim 1, wherein the first area and the second area are a multi-layer having 4 or more layers, and the via is a penetration via that penetrates the second area vertically.

3. The EMI noise reduction board of claim 1, wherein the via is a blind via.

4. The EMI noise reduction board of claim 1, wherein one of the first conductive plate and the second conductive plate has a bump or an indentaion shape corresponding to an outline shape of the first area.

5. The EMI noise reduction board of claim 1, wherein at least any one pair of adjacent conductive plates among the plurality of first conductive plates is electrically connected to each other by a connection line.

6. The EMI noise reduction board of claim 1, wherein the first conductive plate is electrically connected to the ground layer by a connection line.

7. The EMI noise reduction board of claim 1, wherein the second area is selectively arranged in a certain portion of the side portion of the first area.
